(19) United States
(12) Patent Application Publication
(10) Pub. No.: US 2026/0073974 A1
(43) Pub. Date: Mar. 12, 2026

(54) MEMORY DEVICE HAVING SEGMENTED DATA LINE STRUCTURE

(71) Applicant: AP MEMORY TECHNOLOGY CORPORATION, HSINCHU COUNTY (TW)

(72) Inventors: WEN-LIANG CHEN, HSINCHU CITY (TW); LIN MA, HSINCHU COUNTY (TW)

(21) Appl. No.: 19/392,151

(22) Filed: Nov. 18, 2025

Related U.S. Application Data
(63) Continuation of application No. 18/448,525, filed on Aug. 11, 2023, now Pat. No. 12,499,931.
(60) Provisional application No. 63/371,257, filed on Aug. 12, 2022.

(51) Int. Cl. G11C 11/4094; G11C 11/4093; G11C 11/4097

(52) U.S. Cl. CPC G11C 11/4094; G11C 11/4093; G11C 11/4097

(57) ABSTRACT

A memory device includes sets of bitlines, a column selection circuit, and a set of data lines including a first data line and a second data line. The sets of bitlines includes a first set of bitlines and a second set of bitlines. Each data line includes line segments disposed along an extension direction. The column selection circuit couples between the sets of bitlines and the set of data lines. The column selection circuit selectively couples a first bitline in the first set of bitlines and a first bitline in the second set of bitlines to a first line segment and second line segment of the first data line, respectively, and to selectively couple a second bitline in the first set of bitlines and a second bitline in the second set of bitlines to a first line segment of the second data line.

### PRIORITY CLAIM AND CROSS-REFERENCE

This application is a continuation of U.S. non-provisional application Ser. No. 18/448,525, filed on Aug. 11, 2023, which claims the benefit of priority to U.S. provisional application No. 63/371,257, filed on Aug. 12, 2022; the disclosures of all of which are hereby incorporated by reference in their entirety.

### BACKGROUND

The present disclosure relates to memory devices, and more particularly, to a memory device having a segmented data line structure.

Dynamic random-access memory (DRAM) is widely used as a computer's main memory because of its cost-effectiveness. A DRAM device includes a plurality of memory cells, each of which can store a data bit and is usually implemented using a capacitor and a transistor. The capacitor can be charged or discharged to represent a value of the data bit stored in the memory cell. For example, an empty capacitor can denote a logical value of 0, and a fully charged capacitor can denote a logical value of 1. As the technology nodes shrinks, the memory cell gets smaller and the capacitor will store a very limited amount of charge. To provide data that can be interpreted properly, the DRAM device utilizes a sense amplifier to produce an output in the form of recognizable logic levels.

### SUMMARY

The described embodiments provide a memory device having a segmented data line structure.

Some embodiments described herein may include a memory device. The memory device includes a plurality of sets of bitlines, a set of data lines, and a column selection circuit. The plurality of sets of bitlines includes a first set of bitlines and a second set of bitlines. Each data line includes a plurality of line segments disposed along an extension direction. The set of data lines includes a first data line and a second data line. The first data line includes a first line segment and a second line segment adjacent to each other, and the second data line includes a first line segment. The column selection circuit is electrically coupled between the plurality of sets of bitlines and the set of data lines. The column selection circuit is configured to selectively couple a first bitline in the first set of bitlines and a first bitline in the second set of bitlines to the first line segment and the second line segment of the first data line, respectively, and to selectively couple a second bitline in the first set of bitlines and a second bitline in the second set of bitlines to the first line segment of the second data line.

Some embodiments described herein may include a memory device. The memory device includes a plurality of sets of bitlines, a set of data lines, a column selection circuit, and a sense amplifier block. The plurality of sets of bitlines includes a first set of bitlines and a second set of bitlines. Each data line comprising a plurality of line segments separated from each other along an extension direction. The column selection circuit selectively couples the plurality of sets of bitlines to the set of data lines. The sense amplifier block is electrically coupled to the column selection circuit through the plurality of sets of bitlines. The column selection circuit includes a plurality of transistors. Each transistor includes a first node and a second node. The first nodes of the plurality of transistors are electrically coupled to the sense amplifier block, and the second nodes of the plurality of transistors are electrically coupled to the plurality of line segments.

With the use of the proposed data line segmentation scheme, a set of data lines of a memory device can be segmented into line segments to increase memory bandwidth without introducing physical gaps and/or dummy columns in a memory cell array. Data lines that have different numbers of line segments can be of a uniform data width with the use of line segment multiplexing, which can be implemented outside a sense amplifier region to maintain high memory cell density.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram illustrating a partial physical implementation of a memory device in accordance with some embodiments.

FIG. 2 illustrates an implementation of a portion of the memory device shown in FIG. 1 in accordance with some embodiments.

FIG. 3 illustrates an implementation of a portion of the memory device shown in FIG. 1 in accordance with some embodiments.

FIG. 4 illustrates an implementation of a portion of the memory device shown in FIG. 1 in accordance with some embodiments of the present disclosure.

FIG. 5 illustrates an implementation of multiplexing of the line segments shown in FIG. 4 in accordance with some embodiments of the present disclosure.

FIG. 6 illustrates an implementation of a portion of the memory device shown in FIG. 1 in accordance with some embodiments of the present disclosure.

FIG. 7 illustrates an implementation of a portion of the memory device shown in FIG. 1 in accordance with some embodiments of the present disclosure.

FIG. 8 illustrates an implementation of a portion of the memory device shown in FIG. 1 in accordance with some embodiments of the present disclosure.

FIG. 9 is a diagram illustrating an exemplary electr onic package in accordance with some embodiments of the present disclosure.

FIG. 10 illustrates an implementation of a portion of the memory device shown in FIG. 1 in accordance with some embodiments of the present disclosure.

FIG. 11A illustrates an implementation of a portion of the memory device shown in FIG. 1 in accordance with some embodiments of the present disclosure.

FIG. 11B illustrates an implementation of a portion of the memory device shown in FIG. 1 in accordance with some embodiments of the present disclosure.

FIG. 12 illustrates an implementation of a portion of the memory device shown in FIG. 1 in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the present disclosure may repeat reference numerals and/or letters in the various examples. This repetition is for the purpose of simplicity and clarity and does not in itself dictate a relationship between the various embodiments and/or configurations discussed.

Further, it will be understood that when an element is referred to as being “connected to” or “coupled to” another element, it may be directly connected to or coupled to the other element, or intervening elements may be present.

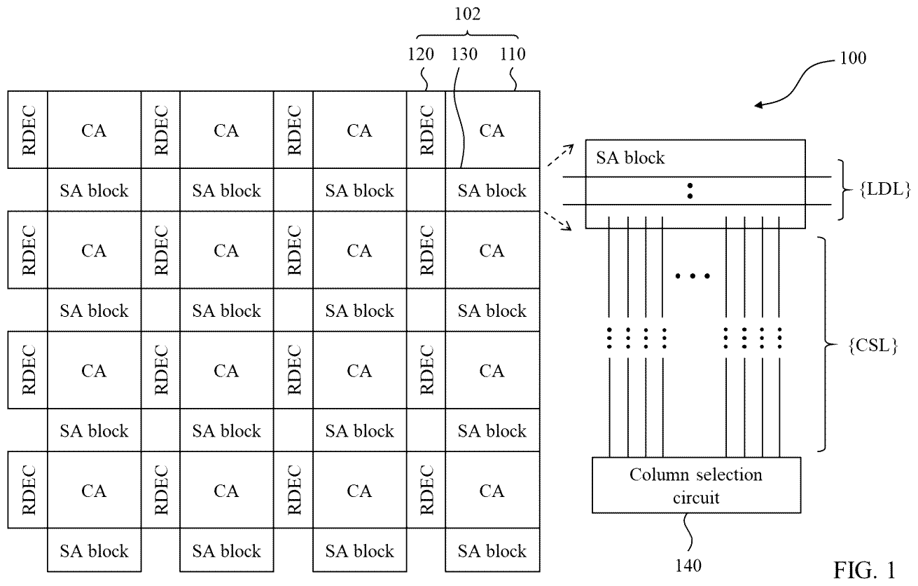

FIG. 1 is a diagram illustrating a partial physical implementation of a memory device in accordance with some embodiments. In the example of FIG. 1, the memory device 100 can be implemented as a DRAM bank, which includes a plurality of tiles 102 arranged in an array. Each tile 102, also referred to as a memory array tile (MAT), may include a cell array (CA) 110, a row decoder (RDEC) 120 and a sense amplifier (SA) block 130. The cell array 110 includes a plurality of storage cells arranged in rows and columns. Storage cells in a given row share a common wordline (not shown) extending in a row direction; storage cells in a given column are coupled to a same bitline (not shown) extending in a column direction. The row decoder 120 is arranged for wordline activation. The sense amplifier block 130 is arranged to sense and amplify data signals on bitlines.

The memory device 100 may be implemented using, but is not limited to, open bitline architecture. For example, in a given row of the cell array 110, a part of storage cells arranged in the row is coupled to one sense amplifier block on the top of the cell array 110 through a part of the bitlines, and another part of the storage cells is coupled to another sense amplifier block on the bottom of the cell array 110 through another part of the bitlines.

The memory device 100 may further include a column selection circuit 140, which is arranged to select sense amplifiers from a sense amplifier block and couple the selected sense amplifiers to a set of data lines. For example, each bitline arranged in the cell array 110 is coupled to an associated sense amplifier of the sense amplifier block 130. The column selection circuit 140 can be configured to activate a column select line in a set of column select lines {CSL} to thereby select a set of bitlines arranged in the cell array 110, and accordingly couple the selected set of bitlines to a set of data lines {LDL}. Each data line in the set of data lines {LDL} can be shared across multiple columns of storage cells in the cell array 110. Note that the memory device 100 may be implemented to have a hierarchical structure, in which the set of data lines {LDL} may be referred to as a set of local data lines that is coupled to a set of global data lines (not shown) arranged along the column direction.

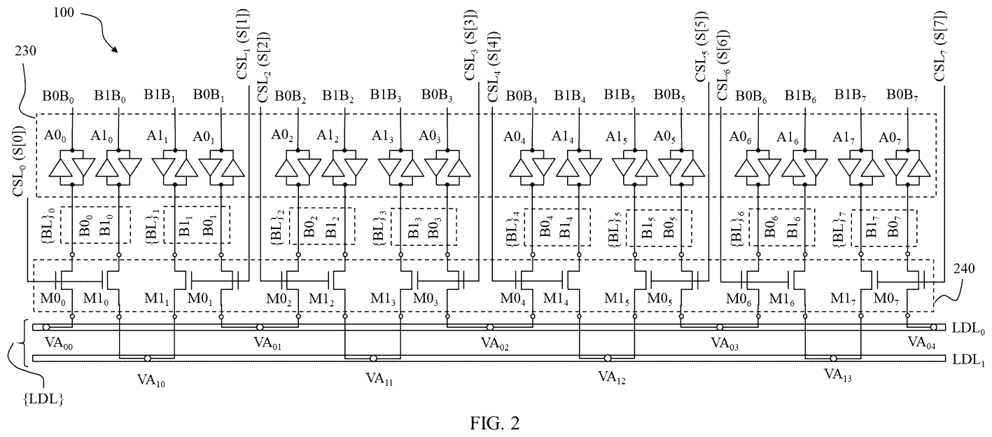

FIG. 2 illustrates an implementation of a portion of the memory device 100 shown in FIG. 1 in accordance with some embodiments. In the example of FIG. 2, the set of data lines {LDL} shown in FIG. 1 can be implemented to include a plurality of data lines LDL₀ and LDL₁, which are shared across the sense amplifier block 230. The column selection circuit 240, controlled by a set of column select signals S[0]-S[7] on the column select lines CSL₀-CSL₇, can be configured to select a set of bitlines from among a plurality of sets of bitlines {BL}₀-{BL}₇ that are coupled to the sense amplifier block 230. The sense amplifier block 230 and the column selection circuit 240 can serve as embodiments of the sense amplifier block 130 and the column selection circuit 140 shown in FIG. 1, respectively. In addition, the column select lines CSL₀-CSL₇ can serve as an embodiment of the set of column select lines {CSL} shown in FIG. 1.

The sense amplifier block 230 may include a plurality of sense amplifiers A0₀-A0₇ and A1₀-A1₇, each of which is coupled to a bitline (i.e. one of the bitlines B0₀-B0₇ and B1₀-B1₇) and a complementary bitline (i.e. one of the complementary bitlines B0B₀-B0B₇ and B1B₀-B1B₇). Each sense amplifier can be implemented using a pair of cross-coupled inverters. In addition, the column selection circuit 240 can be configured to select a set of bitlines from among the sets of bitlines {BL}₀-{BL}₇, and couple the selected set of bitlines to the set of data lines {LDL}. For example, the column selection circuit 240 can be configured to couple the bitlines B0ᵢ and B1ᵢ in the same set of bitlines {BL}ᵢ to the data lines LDL₀ and LDL₁, respectively, according to the same column select signal S[i], where i=0, . . . , 7.

In the example of FIG. 2, each bitline can be coupled to a corresponding data line through the column selection circuit 240 and a corresponding conductive structure (e.g. one of the conductive structures VA₀₀-VA₀₄ and VA₁₀-VA₁₃). Two adjacent bitlines that are selected in response to activation of different column select lines can be coupled to the same data line through a shared conductive structure, such as a conductive via or a contact element. For example, the bitlines B0₁ and B0₂ can be coupled to the data line LDL₀ through a shared conductive structure VA₀₁. Similarly, the bitlines B1₀ and B1₁ can be coupled to the data line LDL₁ through a shared conductive structure VA₁₀.

The column selection circuit 240 may include, but is not limited to, a plurality of transistors M0₀-M0₇ and M1₀-M1₇. The transistor M0ᵢ is arranged to selectively couple the bitline B0ᵢ to the data line LDL₀ according to the column select signal S[i], where i=0, . . . , 7. Thus, the data line LDL₀ can be shared across the sense amplifiers A0₀-A0₇, which are coupled to the bitlines B0₀-B0₇ respectively. Similarly, the transistor M1ᵢ is arranged to selectively couple the bitline B1ᵢ to the data line LDL₁ according to the column select signal S[i], where i=0, . . . , 7. The data line LDL₁ can be shared across the sense amplifiers A1₀-A1₇, which are coupled to the bitlines B1₀-B1₇ respectively.

In operation, when one of the column select lines CSL₀-CSL₇ is activated, the other column select lines are inactivated, and a set of bitlines corresponding to the activated column select line can be coupled to the set of data lines {LDL}. For example, when the column select signal S[0] is logically high, each of the column select signals S[1]-S[7] is logically low. A set of transistors (i.e. the transistors M0₀ and M1₀) is turned on, while the other transistors are turned off. The set of bitlines {BL}₀ (i.e. the bitlines B0₀ and B1₀) is coupled to the set of data lines {LDL}.

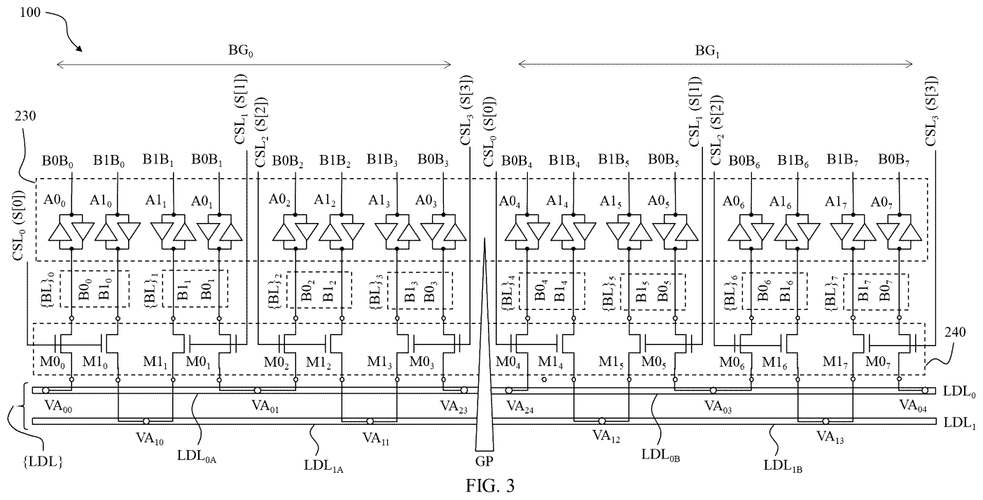

To increase memory bandwidth, a data line shared across a sense amplifier block may be segmented into multiple line segments. FIG. 3 illustrates an implementation of a portion of the memory device 100 shown in FIG. 1 in accordance with some embodiments. The arrangement of the set of data lines {LDL} shown in FIG. 3 is identical/similar to that of the set of data lines {LDL} shown in FIG. 2 except that the data line LDL₀/LDL₁ is segmented into line segments.

In the example of FIG. 3, the sets of bitlines {BL}₀-{BL}₇ can be divided into two bitline groups BG₀ and BG₁. The bitline group BG₀ includes the sets of bitlines {BL}₀-{BL}₃, and the bitline group BG₁ includes the sets of bitlines {BL}₄-{BL}₇. When one of the column select lines CSL₀-CSL₃ is activated, a corresponding set of bitlines in each bitline group is selected and coupled to the set of data lines {LDL}. For example, the sets of bitlines {BL}₀ and {BL}₄ can be selected in response to the activation of the column select line CSL₀. The bitlines B0₀ and B1₀ can be coupled to the line segments LDL_{0A} and LDL_{1A}, respectively. The bitlines B0₄ and B1₄ can be coupled to the line segments LDL_{0B} and LDL_{1B}, respectively.

In addition, when one of the column select lines CSL₀-CSL₃ is activated, memory data transmitted on the data line LDL₀ includes data bits carried by the line segments LDL_{0A} and LDL_{0B}. In other words, the line segments LDL_{0A} and LDL_{0B} are arranged for transmitting different data bits of the memory data. However, separate conductive structures VA₂₃ and VA₂₄, rather than a shared conductive structure, would be needed to couple the bitlines B0₃ and B0₄ to the line segments LDL_{0A} and LDL_{0B}, respectively. A physical gap GP is therefore introduced for providing sufficient space between the conductive structures VA₂₃ and VA₂₄, resulting in an increase in chip area and cost. Moreover, the cell array (e.g. the cell array 110 shown in FIG. 1) will introduce dummy columns to accommodate the gap created in the sense amplifier block 230. Storage cells in each dummy column are left unused during data access, and hence are a waste of chip area.

The present disclosure describes exemplary memory devices, each of which includes a set of data lines that can be segmented into multiple line segments without introducing a physical gap in a memory cell array. For example, each data line included in the exemplary memory device can be segmented at predetermined locations. Each predetermined location lies between two adjacent conductive structures, at least one of which can be shared across two bitlines. Thus, segmenting a data line into line segments would not introduce a physical gap formed between two adjacent conductive structures that are each dedicated to a single bitline.

In some embodiments, each data line can be segmented into more than two line segments. In some embodiments, data lines arranged for transmitting the same number of data bits can be segmented into different numbers of line segments. In some embodiments, line segments of a data line can be multiplexed to accordingly form data of a predetermined bit width. The multiplexing of the line segments may, for example, be implemented outside the sense amplifier region. As another example, the multiplexing of the line segments can be implemented on a wafer that is stacked above or below another wafer where the data line is formed.

With the use of the proposed data line segmentation scheme, a memory device can have high input/output (I/O) bandwidth without introducing physical gaps and/or dummy columns in a memory cell array thereof. For illustrative purposes, the proposed data line segmentation scheme is described below with reference to the segmentation of the set of data lines {LDL} shown in FIG. 2. Those skilled in the art should appreciate that the proposed data line segmentation scheme can be applied to other data line configurations, or applied to other memory devices which include data lines shared across bitlines, without departing from the scope of the present disclosure.

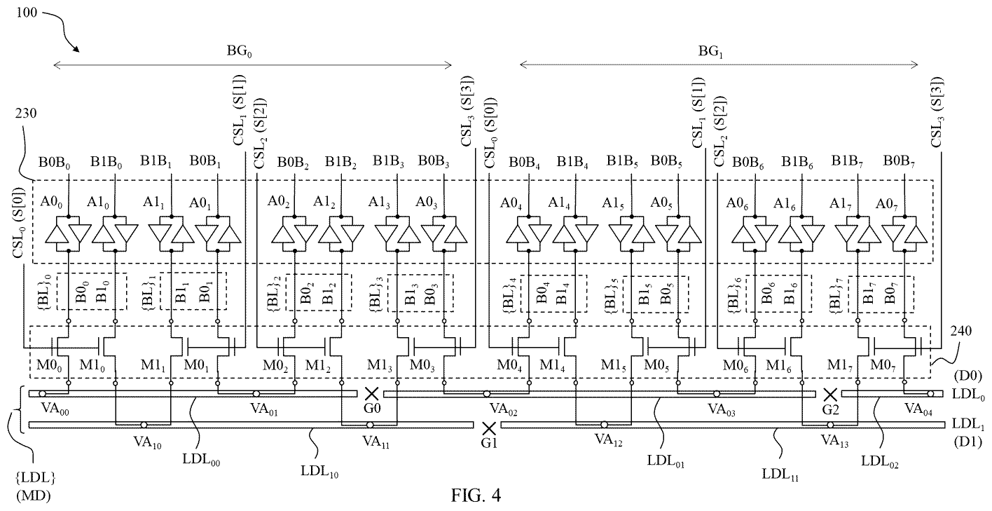

FIG. 4 illustrates an implementation of a portion of the memory device 100 shown in FIG. 1 in accordance with some embodiments of the present disclosure. The arrangement of the set of data lines {LDL} shown in FIG. 4 is identical/similar to that of the set of data lines {LDL} shown in FIG. 2 except that the data line LDL₀/LDL₁ is segmented into line segments separated from each other. Note that the data line LDL₀ and the data line LDL₁ can segmented into a first number of line segments and a second number of line segments, respectively. The second number can be different from the first number.

In the present embodiment, the data line LDL₀ is segmented into line segments LDL₀₀-LDL₀₂, and the data line LDL₁ is segmented into line segments LDL₁₀ and LDL₁₁. The gap G0/G1/G2 created between two adjacent line segments is represented by the symbol X. Each gap is located between two adjacent conductive structures, at least one of which is shared across two bitlines. For example, the gap G0 is located between the conductive structures VA₀₁ and VA₀₂, which are each shared across two bitlines. As another example, the gap G2 is located between the conductive structures VA₀₃ and VA₀₄, and at least the conductive structure VA₀₃ is shared across two bitlines. Note that the conductive structure arrangement shown in FIG. 4 can be substantially identical to that shown in FIG. 2. The data line segmentation scheme shown in FIG. 4 can increase I/O bandwidth without introducing additional conductive structures and physical gaps. There can be no dummy storage cells arranged between two adjacent bitlines near a gap (e.g. the bitlines B1₂ and B1₃ near the gap G0).

In addition, two sets of bitlines near a gap can be coupled to two adjacent line segments of one data line while coupled to a same line segment of another data line. For example, the bitline B0₂ in the set of bitlines {BL}₂ and a first bitline B0₃ in the set of bitlines {BL}₃ are selectively coupled to the line segment LDL₀₀ and the line segment LDL₀₁ of the data line LDL₀ through the column selection circuit 240, respectively; the bitline B1₂ in the set of bitlines {BL}₂ and the bitline B1₃ in the set of bitlines {BL}₃ are each selectively coupled to the line segment LDL₁₀ of the data line LDL₁ through the column selection circuit 240.

In the example of FIG. 4, the sets of bitlines {BL}₀-{BL}₇ can be divided into two bitline groups BG₀ and BG₁. The bitline group BG₀ includes the sets of bitlines {BL}₀-{BL}₃, and the bitline group BG₁ includes the sets of bitlines {BL}₄-{BL}₇. The column selection circuit 240 can be configured to select one set of bitlines from each bitline group, and couple the selected set of bitlines to the set of data lines {LDL}. Bitlines in the selected set of bitlines can be coupled to the data line LDL₀ and the data line LDL₁, respectively. For example, the column selection circuit 240 may couple the set of bitlines {BL}₀ in the bitline group BG₀ and the set of bitlines {BL}₄ in the bitline group BG₁ to the set of data lines {LDL} in response to activation of the column select line CSL₀. The bitlines B0₀ and B0₄ are coupled to the data line LDL₀, and the bitlines B1₀ and B1₄ are coupled to and the data line LDL₁.

Moreover, the column selection circuit 240 can be arranged to couple the sets of bitlines in the one bitline group to a first line segment and a second line segment of the data line LDL₀, and to a first line segment of the data line LDL₁. The column selection circuit 240 can be further arranged to couple the sets of bitlines in the another bitline group to the second line segment and a third line segment of the data line LDL₀, and to a second line segment of the data line LDL₁. Different bitlines in the same bitline group may be coupled to separate line segments of the same data line. For example, the bitline B0₀/B0₁/B0₂ in the bitline group BG₀ can be coupled to the line segment LDL₀₀ when selected by the column selection circuit 240; the bitline B0₃ in the bitline group BG₀ can be coupled to the line segment LDL₀₁ when selected by the column selection circuit 240.

In operation, when one of the column select lines CSL₀-CSL₃ is activated, the other column select lines are inactivated. The column selection circuit 240 can couple a corresponding set of bitlines in each bitline group to the set of data lines {LDL} to thereby transmit memory data MD, which may be inputted to or outputted from a cell array. The data line LDL₀ can be arranged to transmit (i.e. input or output) a set of data bits D0 of the memory data MD, and the data line LDL₁ can be arranged to transmit a set of data bits D1 of the memory data MD. For brevity, the operation of the memory device 100 is described by outputting the data from the cell array to the data lines LDL₀ and LDL₁. This is not a limitation of the present invention. Those skilled in the art should appreciate that inputting the data into the cell array from the data lines LDL₀ and LDL₁ also belongs to the scope of the present invention.

For example, when the column select line CSL₀ is activated, the transistors M0₀ and M1₀ are turned on to select the set of bitlines {BL} ₀ in the bitline group BG₀. The bitline B0₀ is coupled to the line segment LDL₀₀ of the data line LDL₀ to output a data bit in the set of data bits D0. The bitline B1₀ is coupled to the line segment LDL₁₀ of the data line LDL₁ to output a data bit in the set of data bits D1. Similarly, when the column select line CSL₁/CSL₂ is activated, the line segment LDL₀₀ can be arranged to output a data bit in the set of data bits D0, and the line segment LDL₁₀ can be arranged to output a data bit in the set of data bits D1. In addition, when the column select line CSL₃ is activated, the bitline B0₃ is coupled to the line segment LDL₀₁ separated from the line segment LDL₀₀, thereby outputting a data bit in the set of data bits D0. The bitline B1₃ is coupled to the line segment LDL₁₀ in response to activation of the column select line CSL₃, thereby outputting a data bit in the set of data bits D1.

With regard to the bitline group BG₁, when the column select line CSL₀ is activated, the column selection circuit 240 can couple the bitline B0₄ to the line segment LDL₀₁ to thereby output a data bit in the set of data bits D0. The column selection circuit 240 can further couple the bitline B1₄ to the line segment LDL₁₁ to thereby output a data bit in the set of data bits D1. Similarly, when the column select line CSL₁/CSL₂ is activated, the line segment LDL₀₁ can be arranged to output a data bit in the set of data bits D0, and the line segment LDL₁₁ can be arranged to output a data bit in the set of data bits D1. When the column select line CSL₃ is activated, the column selection circuit 240 can couple the bitlines B0₇ and B1₇ to the line segments LDL₀₂ and LDL₁₁, respectively.

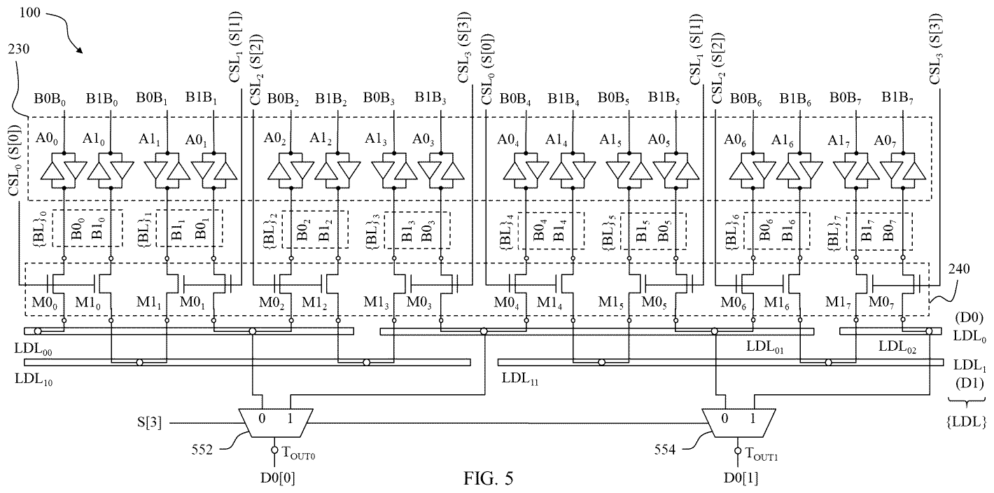

In some embodiments, a predetermined data bit in the set of data bits D0 can be transmitted on the line segment LDL₀₀ when the set of bitlines {BL}₀/{BL}₁/{BL}₂ is selected, and can be transmitted on the line segment LDL₀₁ when the set of bitlines {BL}₃ is selected. In other words, when the set of bitlines {BL}₀/{BL}₁/{BL}₂ is selected, the column selection circuit 240 is configured to couple the bitline B0₀/B0₁/B0₂ to the line segment LDL₀₀ of the data line LDL₀ to output the predetermined data bit; when the set of bitlines {BL}₃ is selected, the column selection circuit 240 is configured to couple the bitline B0₃ to the line segment LDL₀₁ of the data line LDL₀ to output the predetermined data bit. In addition, another predetermined data bit in the set of data bits D0 can be outputted on the line segment LDL₀₁ when the set of bitlines {BL}₄/{BL}₅/{BL}₆ is selected, and can be outputted on the line segment LDL₀₂ when the set of bitlines {BL}₇ is selected. Thus, the data lines LDL₀ and LDL₁ that differ in the number of line segments may have different data width. Specifically, in this embodiment, the data width of the data line LDL₀ is 3 bits and the data width of the data line LDL₁ is 2 bits. In the following FIG. 5 and related paragraphs, a method is proposed to make the data lines LDL₀ and LDL₁ to be of uniform data width (e.g. 2 bits).

For example, when the column select line CSL₀/CSL₁/CSL₂ is activated, the line segments LDL₀₀ and LDL₀₁ of the data line LDL₀ can be arranged to output a first data bit and a second data bit of the set of data bits D0, respectively. When the column select line CSL₃ is activated, the line segments LDL₀₁ and LDL₀₂ of the data line LDL₀ can be arranged to output the second data bit and the third data bit of the set of data bits D0, respectively. On the other hand, with regard to the data line LDL₁, the line segments LDL₁₀ and LDL₁₁ can be arranged to output a first data bit and a second data bit of the set of data bits D1, respectively, in response to the activation of the column select line CSL₀/CSL₁/CSL₂/CSL₃.

Note that bitlines selected in response to activation of a same column select line can be regarded as belonging to a same set of bitlines in the memory device 100. For example, the bitlines B0₀, B1₀, B0₄ and B1₄ can be regarded as belonging to the same set of bitlines in the memory device 100 since they can be selected in response to activation of the same column select line CSL₀. Similarly, the bitlines B0₁, B1₁, B0₅ and B1₅ can be regarded as belonging to the same set of bitlines; the bitlines B0₂, B1₂, B0₆ and B1₆ can be regarded as belonging to the same set of bitlines; the bitlines B0₃, B1₃, B0₇ and B1₇ can be regarded as belonging to the same set of bitlines.

In some embodiments, line segments of the data line LDL₀ can be multiplexed to make the data width of the data lines LDL₀ to be equal to that of the data line LDL₁. FIG. 5 illustrates an implementation of multiplexing of the line segments LDL₀₀-LDL₀₂ shown in FIG. 4 in accordance with some embodiments of the present disclosure. In the present embodiment, the memory device 100 may further include a plurality of multiplexer circuits 552 and 554. Each of the multiplexer circuits 552 and 554 may be disposed outside a sense amplifier region in which the sense amplifier block 230 is implemented.

The multiplexer circuit 552 can be configured to couple one of the line segments LDL₀₀ and LDL₀₁ to an output terminal T_{OUT0} thereof according to whether a predetermined set of bitlines is selected. For example, the multiplexer circuit 552 can be configured to receive the column select signal S[3], which can indicate whether the set of bitlines {BL}₃ is selected. When the set of bitlines {BL}₃ is unselected, the column select signal S[3] is logically low. The multiplexer circuit 552 can couple the line segment LDL₀₀ to the output terminal T_{OUT0} according to the column select signal S[3]. When the set of bitlines {BL}₃ is selected, the column select signal S[3] is logically high. The multiplexer circuit 552 can couple the line segment LDL₀₁ to the output terminal T_{OUT0} according to the column select signal S[3].

Similarly, the multiplexer circuit 554 can be configured to couple one of the line segments LDL₀₁ and LDL₀₂ to an output terminal T_{OUT1} thereof according to whether a predetermined set of bitlines is selected. In the example of FIG. 5, the multiplexer circuit 554 can be configured to receive the column select signal S[3] to select one of the line segments LDL₀₁ and LDL₀₂, thereby coupling the selected line segment to the output terminal T_{OUT1}.

In operation, when the column select line CSL₀/CSL₁/CSL₂ is activated to select a corresponding set of bitlines in each bitline group, the line segments LDL ₀₀ and LDL₀₁ are coupled to the output terminals T_{OUT0} and T_{OUT1}, respectively. The data bits D0[0] and D0[1] correspond to respective data bits transmitted on the line segments LDL₀₀ and LDL₀₁. When the column select line CSL₃ is activated to select a corresponding set of bitlines in each bitline group, the line segments LDL₀₁ and LDL₀₂ are coupled to the output terminals T_{OUT0} and T_{OUT1}, respectively. The data bits D0[0] and D0[1] correspond to respective data bits transmitted on the line segments LDL₀₁ and LDL₀₂. In other words, the multiplexer circuits 552 and 554 are arranged to reduce the data width into 2 bits (i.e. the data bits D0[0] and D0[1]) from the 3 bits of the data line LDL₀ in order to form a data width equal to that of the data line LDL₁.

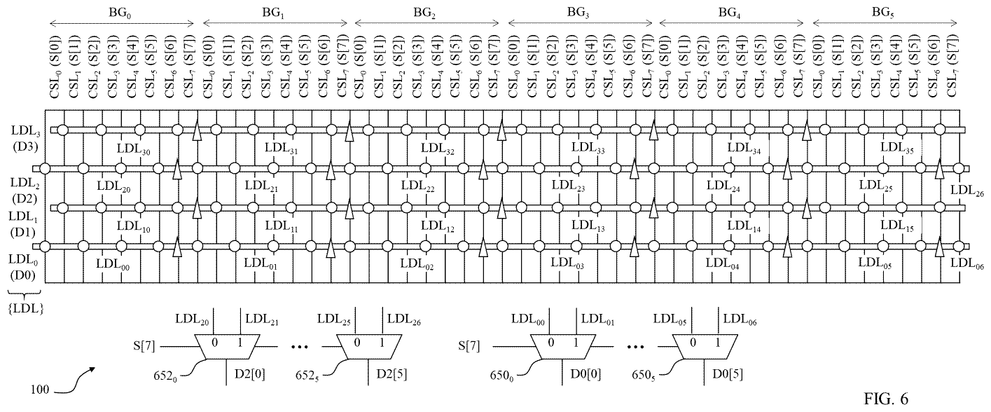

FIG. 6 illustrates an implementation of a portion of the memory device 100 shown in FIG. 1 in accordance with some embodiments. The segmentation of the set of data lines {LDL} shown in FIG. 6 can serve as a more generalized embodiment of segmentation of the set of data lines {LDL} shown in FIG. 4. Each data line shown in FIG. 6 can be segmented into more than two line segments according to the method as disclosed in FIG. 4.

Referring to FIG. 6, the set of data lines {LDL} includes a plurality of data lines LDL₀-LDL₃. The data lines LDL₀-LDL₃ can be arranged to output the sets of data bits D0-D3, respectively. The number of line segments of the data line LDL₀/LDL₂ can be greater than the number of line segments of the data line LDL₁/LDL₃ by one. A corresponding set of bitlines (not shown) in each of the bitline groups BG₀-BG₅ can be selected in response to activation of one of the column select lines CSL₀-CSL₇. For each bitline group, four bitlines in the selected set of bitlines (not shown) can be coupled to the data lines LDL₀-LDL₃, respectively when one of the column select signals S[0]-S[7] is activated. For example, a column selection circuit (not shown), implemented based on the column selection circuit 240 shown in FIG. 4, may be configured to receive the column select signals S[0]-S[7] on the column select lines CSL₀-CSL₇ to control the bitline selection. In addition, each circle can represent a conductive structure arranged for coupling a selected bitline to a corresponding line segment. Each triangle is a gap, and is a symbol to indicate the two adjacent line segments are separated.

In the present embodiment, the segmentation of the data line LDL₀/LDL₂ can be implemented based on the segmentation applied to the data line LDL₀ shown in FIG. 4. For example, the data line LDL₀ can be segmented into a plurality of line segments LDL₀₀-LDL₀₆. When one of the column select lines CSL₀-CSL₆ is activated, the selected bitlines in the bitline groups BG₀-BG₅ are coupled to the line segments LDL₀₀-LDL₀₅, respectively; when the column select line CSL₇ is activated, the selected bitlines in the bitline groups BG₀-BG₅ are coupled to the line segment LDL₀₁-LDL₀₆, respectively. Similarly, the data line LDL₂ can be segmented into a plurality of line segments LDL₂₀-LDL₂₆. When one of the column select lines CSL₀-CSL₆ is activated, the selected bitlines in the bitline groups BG₀-BG₅ are coupled to the line segments LDL₂₀-LDL₂₅, respectively; when the column select line CSL₇ is activated, the selected bitlines in the bitline groups BG₀-BG₅ are coupled to the line segment LDL₂₁-LDL₂₆, respectively.

In addition, the segmentation of the data line LDL₁/LDL₃ can be implemented based on the segmentation applied to the data line LDL₁ shown in FIG. 4. For example, the data line LDL₁ can be segmented into a plurality of line segments LDL₁₀-LDL₁₅. When one of the column select lines CSL₀-CSL₇ is activated, the selected bitlines in the bitline groups BG₀-BG₅ are coupled to the line segments LDL₁₀-LDL₁₅, respectively. Similarly, the data line LDL₃ can be segmented into a plurality of line segments LDL₃₀-LDL₃₅. When one of the column select lines CSL₀-CSL₇ is activated, the selected bitlines in the bitline groups BG₀-BG₅ are coupled to the line segments LDL₃₀-LDL₃₅, respectively.

Accordingly, the data widths of the data lines LDL₀ and LDL₂ are 7 bits, and the data widths of the data lines LDL₁ and LDL₃ are 6 bits. Then, line segments of the data line LDL₀/LDL₂ can be multiplexed to implement a data width equal to that of the data line LDL₁/LDL₃. In the present embodiment, the memory device 100 may further include a plurality of multiplexer circuits 650₀-650₅ and 652₀-652₅ to implement the line segment multiplexing. Each multiplexer circuit may be disposed outside a sense amplifier region of the memory device 100.

Each of the multiplexer circuits 650₀-650₅ can be configured to select one of two adjacent line segments of the data line LDL₀ according to whether the column select line CSL₇ is activated. For example, the multiplexer circuit 650ᵢ is configured to select one of the line segments LDL₀ᵢ and LDL₀ⱼ according to whether the column select line CSL₇ is activated, thereby outputting and forming the data bit D0[i] of the set of data bits D0, where i=0, . . . , 5, and j=i+1. Similarly, each of the multiplexer circuits 652₀-652₅ can be configured to select one of two adjacent line segments of the data line LDL₂ according to whether the column select line CSL₇ is activated. For example, the multiplexer circuit 652ᵢ is configured to select one of the line segments LDL₂ᵢ and LDL₂ⱼ according to whether the column select line CSL₇ is activated, thereby outputting and forming the data bit D2[i] of the set of data bits D2, where i=0, . . . , 5, and j=i+1. By using the multiplexer circuits 650₀-650₅, the data width of the data line LDL₀ is reduced to 6 bits (i.e. D0[0]-D0[5]) from 7 bits, and the data width of the data line LDL₂ is reduced to 6 bits (i.e. D2[0]-D2[5]) from 7 bits. Accordingly, the data lines LDL₀, LDL₁, LDL₂ and LDL₃ are of uniform data width.

In the example of FIG. 6, each multiplexer circuit can be controlled by the column select signal S[7] on the column select line CSL₇. The line segments LDL₀₀-LDL₀₅ and LDL₂₀-LDL₂₅ are selected when the column select signal S[7] is logically low. The line segments LDL₀₁-LDL₀₆ and LDL₂₁-LDL₂₆ are selected when the column select signal S[7] is logically high. As those skilled in the art can appreciate the data line segmentation shown in FIG. 6 and associated line segment multiplexing after reading the above paragraphs directed to FIG. 1 to FIG. 5, further description is omitted here for brevity.

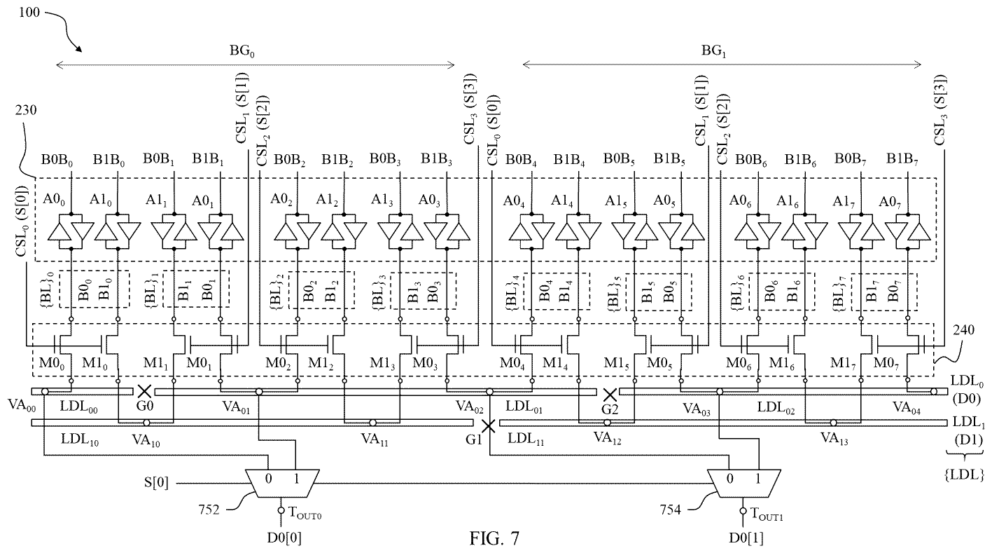

The data line segmentation shown in FIG. 4 to FIG. 6 is provided for illustrative purposes, and is not intended to limit the scope of the present disclosure. In some embodiments, the data line LDL₀ shown in FIG. 4 and/or FIG. 5 can be split into line segments at other positions without departing from the scope of the present disclosure. FIG. 7 illustrates an implementation of a portion of the memory device 100 shown in FIG. 1 in accordance with some embodiments. The arrangement of the set of data lines {LDL} shown in FIG. 7 is identical/similar to that shown in FIG. 4 or FIG. 5 except for the locations of the gaps G0 and G2.

In the example of FIG. 7, the gap G0 can be created between the conductive structures VA₀₀ and VA₀₁, and the gap G2 can be created between the conductive structures VA₀₂ and VA₀₃. Regarding the bitline group BG₀, the bitline B0₀ is coupled to the line segment LDL₀₀ when selected by the column selection circuit 240, whereas the bitline B0₁/B0₂/B0₃ is coupled to the line segment LDL₀₁ when selected by the column selection circuit 240. Regarding the bitline group BG₁, the bitline B0₄ is coupled to the line segment LDL₀₁ when selected by the column selection circuit 240, whereas the bitline B0₅/B0₆/B0₇ is coupled to the line segment LDL₀₂ when selected by the column selection circuit 240.

The line segments LDL₀₀-LDL₀₂ of the data line LDL₀ can be multiplexed to implement a data width equal to that of the data line LDL₁. For example, the multiplexer circuit 752 can be arranged to couple one of the line segments LDL₀₀ and LDL₀₁ to the output terminal T_{OUT0} according to whether a predetermined set of bitlines (i.e. the set of bitlines {BL}₀) is selected. The selection of the line segments LDL₀₀ and LDL₀₁ can be controlled by the column select signal S[0]. In addition, the multiplexer circuit 754 can be arranged to couple one of the line segments LDL₀₁ and LDL₀₂ to the output terminal T_{OUT1} according to whether a predetermined set of bitlines (i.e. the set of bitlines {BL}₄) is selected. The selection of the line segments LDL₀₁ and LDL₀₂ can be controlled by the column select signal S[0]. As those skilled in the art can appreciate the operation associated with line segment multiplexing shown in FIG. 7 after reading the above paragraphs directed to FIG. 1 to FIG. 6, further description is omitted here for brevity.

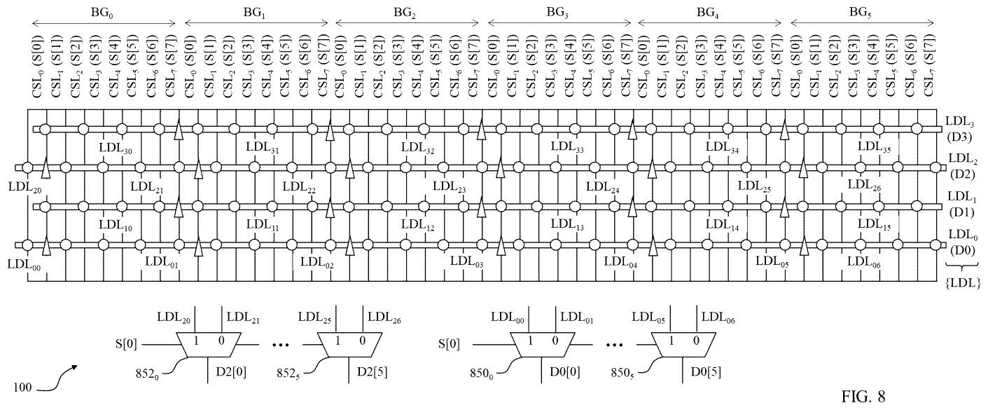

FIG. 8 illustrates an implementation of a portion of the memory device 100 shown in FIG. 1 in accordance with some embodiments. The segmentation of the set of data lines {LDL} shown in FIG. 8 can serve as a more generalized embodiment of segmentation of the set of data lines {LDL} shown in FIG. 7. In the present embodiment, the arrangement of the set of data lines {LDL} is substantially identical/similar to that shown in FIG. 6 except for the gap locations associated with the data lines LDL₀ and LDL₂. In addition, the column select lines CSL₀-CSL₇ can be used to control the selection of the bitlines included in the bitline groups BG₀-BG₅ in a manner similar to that described above with reference to FIG. 7.

The segmentation of the data line LDL₀/LDL₂ can be implemented based on the segmentation applied to the data line LDL₀ shown in FIG. 7. For example, the data line LDL₀ can be segmented into a plurality of line segments LDL₀₀-LDL₀₆. When the column select line CSL₀ is activated, the selected bitlines in the bitline groups BG₀-BG₅ are coupled to the line segment LDL₀₀-LDL₀₅, respectively; when one of the column select lines CSL₁-CSL₇ is activated, the selected bitlines in the bitline groups BG₀-BG₅ are coupled to the line segments LDL₀₁-LDL₀₆, respectively. Similarly, the data line LDL₂ can be segmented into a plurality of line segments LDL₂₀-LDL₂₆. When the column select line CSL₀ is activated, the selected bitlines in the bitline groups BG₀-BG₅ are coupled to the line segment LDL₂₀-LDL₂₅, respectively; when one of the column select lines CSL₁-CSL₇ is activated, the selected bitlines in the bitline groups BG₀-BG₅ are coupled to the line segments LDL₂₁-LDL₂₆, respectively.

In addition, line segments of the data line LDL₀/LDL₂ can be multiplexed to implement a data width equal to that of the data line LDL₁/LDL₃. By way of example but not limitation, the memory device 100 may further include a plurality of multiplexer circuits 850₀-850₅ and 852₀-852₅ to implement the line segment multiplexing. The multiplexer circuit 850ᵢ is configured to select one of the line segments LDL₀ᵢ and LDL₀ⱼ according to the column select signal S[0] on the column select line CSL₀, thereby outputting and forming the data bit D0[i] of the set of data bits D0, where i=0, . . . , 5, and j=i+1. Similarly, the multiplexer circuit 852ᵢ is configured to select one of the line segments LDL₂ᵢ and LDL₂ⱼ according to the column select signal S[0], thereby outputting and forming the data bit D2[i] of the set of data bits D2, where i=0, . . . , 5, and j=i+1. The line segments LDL₀₀-LDL₀₅ and LDL₂₀-LDL₂₅ are selected when the column select signal S[0] is logically high. The line segments LDL₀₁-LDL₀₆ and LDL₂₁-LDL₂₆ are selected when the column select signal S[0] is logically low.

As those skilled in the art can appreciate the data line segmentation shown in FIG. 8 and associated line segment multiplexing after reading the above paragraphs directed to FIG. 1 to FIG. 7, further description is omitted here for brevity.

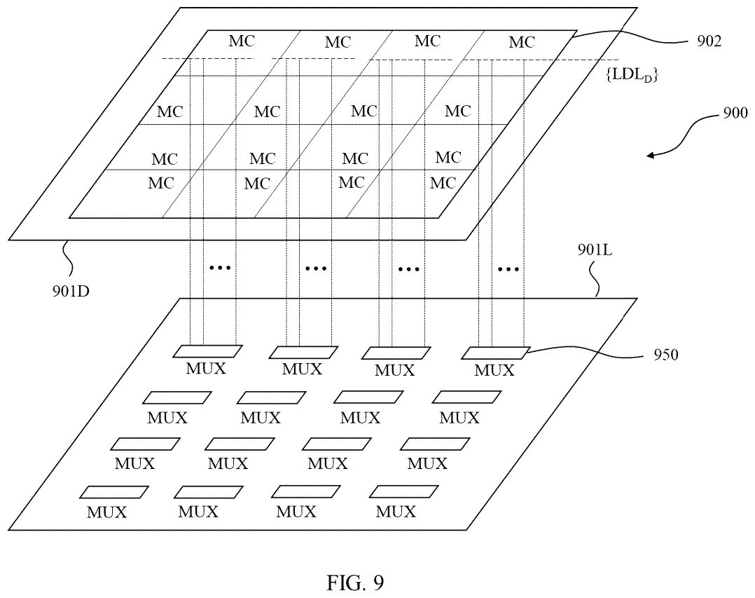

FIG. 9 is a diagram illustrating an exemplary electronic package in accordance with some embodiments of the present disclosure. The electronic package 900 can serve as an embodiment of the memory device 100 shown in FIG. 1 which employs the proposed data line segmentation scheme. In the present embodiment, the electronic package 900 may be a memory device implemented using wafer-on-wafer (WoW) technology. The semiconductor substrates (or wafers) 901D and 901L of the electronic package 900 can be stacked one above the other.

A plurality of memory macros (MC) 902 may be formed on the semiconductor substrate 901D. Each memory macro 902 may include one or more memory banks. Each memory bank can include at least one array of tiles that can be implemented using the array of tiles shown in FIG. 1. By way of example but not limitation, each memory macro 902 may be implemented as a DRAM macro, and the semiconductor substrate 901D may be referred to as a DRAM wafer. In addition, a plurality of sets of data lines can be formed on the semiconductor substrate 901D to transmit a plurality of sets of data bits, respectively. Each set of data lines can be segmented based on the proposed data line segmentation scheme. For example, the set of data lines {LDL_{D}} can be implemented using the set of data lines {LDL} shown in FIG. 4 to FIG. 8.

A plurality of multiplexer blocks (MUX) 950 may be formed on the semiconductor substrate 901L, which may be referred to as a logic wafer. Each multiplexer block 950 can include a plurality of multiplexer circuits to implement the line segment multiplexing. By way of example but not limitation, the set of data lines {LDL_{D}} may be implemented to include the set of data lines {LDL} shown in FIG. 5, and the multiplexer block 950 may be implemented to include the multiplexer circuits 552 and 554 shown in FIG. 5. In some embodiments, the multiplexer block 950 may be implemented using the multiplexer circuits 650₀-650₅ and 652₀-652₅ shown in FIG. 6, the multiplexer circuits 752 and 754 shown in FIG. 7, and/or the multiplexer circuits 850₀-850₅ and 852₀-852₅ shown in FIG. 8.

As those skilled in the art can appreciate the data line segmentation shown in FIG. 9 and associated line segment multiplexing after reading the above paragraphs directed to FIG. 1 to FIG. 8, further description is omitted here for brevity.

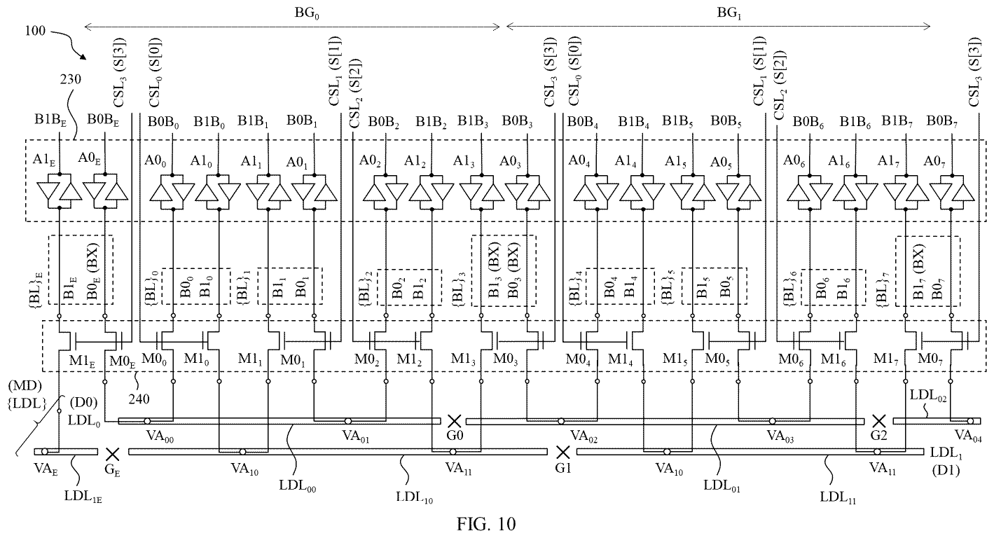

FIG. 10 illustrates an implementation of a portion of the memory device 100 shown in FIG. 1 in accordance with some embodiments of the present disclosure. The arrangement of the set of data lines {LDL} shown in FIG. 10 is substantially identical/similar to that shown in FIG. 4 except that the data line LDL₁ can further include a line segment LDL_{1E}. The line segments LDL_{1E} and LDL₁₀ are separated by a gap G_{E}. In addition, the bitline arrangement shown in FIG. 10 is substantially identical/similar to that shown in FIG. 4 except that a set of bitlines {BL}_{E} can be arranged at the left side of the set of bitlines {BL}₀. The set of bitlines {BL}_{E} can be coupled to the set of data lines {LDL} through the column selection circuit 240 in response to activation of the column select line CSL₃.

In the present embodiment, the sense amplifier block 230 can further include sense amplifiers A0_{E} and A1_{E}, each of which can be implemented using a pair of cross-coupled inverters. The sense amplifier A0_{E} is coupled to the bitline B0_{E} and the complementary bitline B0B_{E}, and the sense amplifier A1_{E} is coupled to the bitline B1_{E} and the complementary bitline B1B_{E}. The column selection circuit 240 can be configured to selectively couple the set of bitlines {BL}_{E} to the data lines {LDL} according to the column select signal S[3]. For example, the column selection circuit 240 may include transistors M0_{E} and M1_{E}. The transistor M0_{E} is arranged for selectively coupling the bitline B0_{E} to the data line LDL₀₀ through the conductive structure VA₀₀ according to the column select signal S[3]; the transistor M1_{E} is arranged for selectively coupling the bitline B1_{E} to the data line LDL_{1E} through the conductive structure VA_{E} according to the column select signal S[3].

In the example of FIG. 10, the sets of bitlines {BL} _{E} and {BL}₀-{BL}₇ can be utilized to implement two bitline groups BG₀ and BG₁. The bitline group BG₀ includes the sets of bitlines {BL}₀-{BL}₂, and the bitlines B0_{E} and B1₃. The bitlines B0_{E} and B1₃ can be regarded as being included in the same set of bitlines BX since both of them can be selected in response to activation of the same column select line CSL₃. In addition, a first bitline in the set of bitlines {BL}₀/{BL}₁/{BL}₂ (e.g. the bitline B0₀/B0₁/B0₂) and a first bitline in the set of bitlines BX (e.g. the bitline B0_{E}) are selectively coupled to the line segment LDL₀₀ through the column selection circuit 240; a second bitline in the set of bitlines {BL}₀/{BL}₁/{BL}₂ (e.g. the bitline B1₀/B1₁/B1₂) and a second bitline in the set of bitlines BX (e.g. the bitline B1₃) are selectively coupled to the line segment LDL₁₀ through the column selection circuit 240. The set of bitlines {BL}₀/{BL}₁/{BL}₂ is arranged between the first bitline and the second bitline in the set of bitlines BX.

The bitline group BG₁ includes the sets of bitlines {BL}₄-{BL}₆, and the bitlines B0₃ and B1₇. Similarly, the bitlines B0₃ and B1₇ can be regarded as being included in the set of bitlines BX since both of them can be selected in response to activation of the same column select line CSL₃. The set of bitlines {BL}₄/{BL}₅/{BL}₆ is arranged between the bitlines B0₃ and B1₇ in the set of bitlines BX.

In operation, when one of the column select lines CSL₀-CSL₃ is activated, the other column select lines are inactivated. The column selection circuit 240 can couple a corresponding set of bitlines in each bitline group to the set of data lines {LDL} to thereby transmit the memory data MD, which may be inputted to or outputted from a cell array. The data line LDL₀ can be arranged to transmit (i.e. output or input) a set of data bits D0 of the memory data MD, and the data line LDL₁ can be arranged to transmit a set of data bits D1 of the memory data MD.

For example, when the set of bitlines {BL}₀/{BL}₁/{BL}₂ in the bitline group BG₀ is selected in response to activation of a corresponding column select line (i.e. one of the column select lines CSL₀-CSL₂), the column selection circuit 240 can couple the bitline B0₀/B0₁/B0₂ to the line segment LDL₀₀ to thereby transmit (e.g. output or input) a predetermined data bit of the set of data bits D0, and couple the bitline B1₀/B1₁/B1₂ to the line segment LDL₁₀ to thereby transmit a predetermined data bit of the set of data bits D1. In addition, when the set of bitlines BX is selected, the column selection circuit 240 can couple the bitline B0_{E} in the bitline group BG₀ to the line segment LDL₀₀ to thereby transmit the predetermined data bit of the set of data bits D0, and couple the bitline B1₃ in the bitline group BG₀ to the line segment LDL₁₀ to thereby transmit the predetermined data bit of the set of data bits D1.

With regard to the bitline group BG₁, when the set of bitlines {BL}₄/{BL}₅/{BL}₆ in the bitline group BG₁ is selected in response to activation of a corresponding column select line (i.e. one of the column select lines CSL₀-CSL₂), the column selection circuit 240 can couple the bitline B0 ₄/B0₅/B0₆ to the line segment LDL₀₁ to thereby transmit another predetermined data bit of the set of data bits D0, and couple the bitline B1₄/B1₅/B1₆ to the line segment LDL₁₁ to thereby transmit another predetermined data bit of the set of data bits D1. In addition, when the set of bitlines BX is selected, the column selection circuit 240 can couple the bitline B0₃ to the line segment LDL₀₁ to thereby transmit the another predetermined data bit of the set of data bits D0, and couple the bitline B1₇ to the line segment LDL₁₁ to thereby transmit the another predetermined data bit of the set of data bits D1. Note that the bitlines B1₃ and B0₃ in the same set of bitlines BX are adjacent to each other, while belong to different bitline groups.

Accordingly, by arranging the line segment LDL_{1E} and related circuits (e.g. the set of bitlines {BL}_{E}) at the left side of the memory device 100, the data line LDL₀ and LDL₁ can have uniform data width (i.e. 2 bits) without using additional multiplexers in FIG. 5.

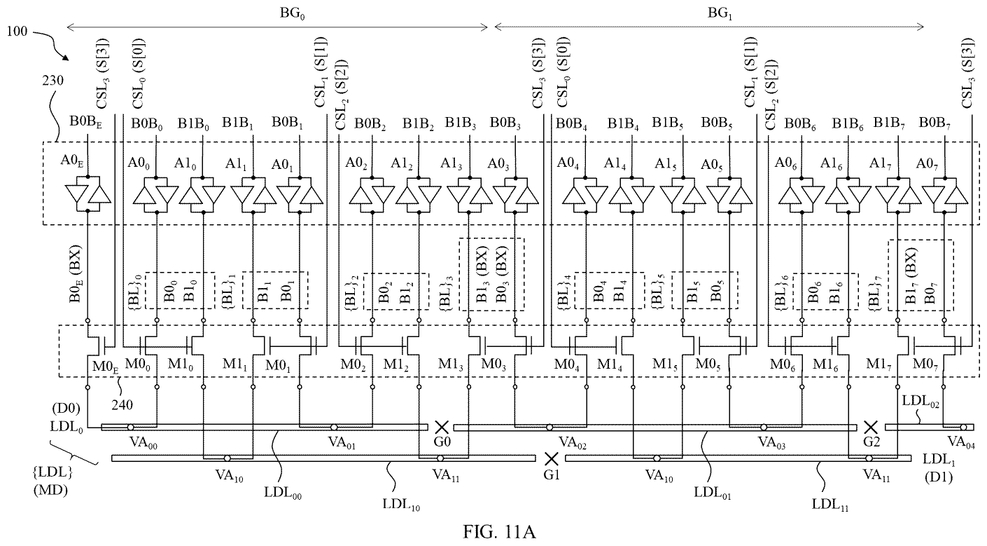

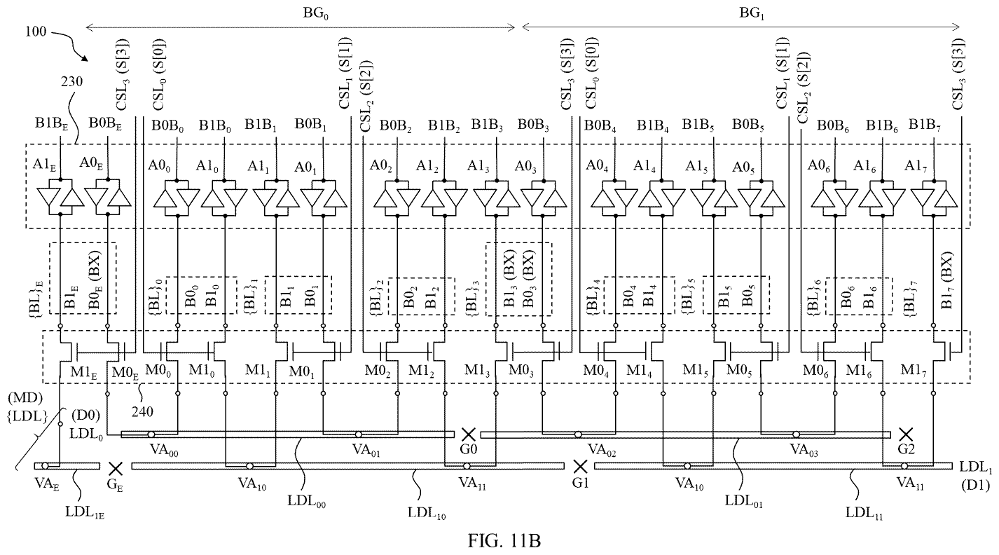

In some embodiments, the line segment LDL_{1E} shown in FIG. 10 may be optional when the bitline group BG₀ is the leftmost one among bitline groups of the memory device 100. Thus, the associated elements (e.g. the bitline B1_{E}, the complementary bitline B1B_{E}, the sense amplifier A1_{E}, the transistor M1_{E} and the conductive structure VA_{E}) can be omitted, as illustrated in FIG. 11A.

In some embodiments, the line segment LDL₀₂ shown in FIG. 10 may be optional when the bitline group BG₁ is the rightmost one among bitline groups of the memory device 100. Thus, the associated elements (e.g. the bitline B0₇, the complementary bitline B0B₇, the sense amplifier A0₇, the transistor M0₇ and the conductive structure VA₀₄) can be omitted, as illustrated in FIG. 11B.

As those skilled in the art can appreciate the data line segmentation shown in FIG. 10 to FIG. 11B and associated data access operation after reading the above paragraphs directed to FIG. 1 to FIG. 9, further description is omitted here for brevity.

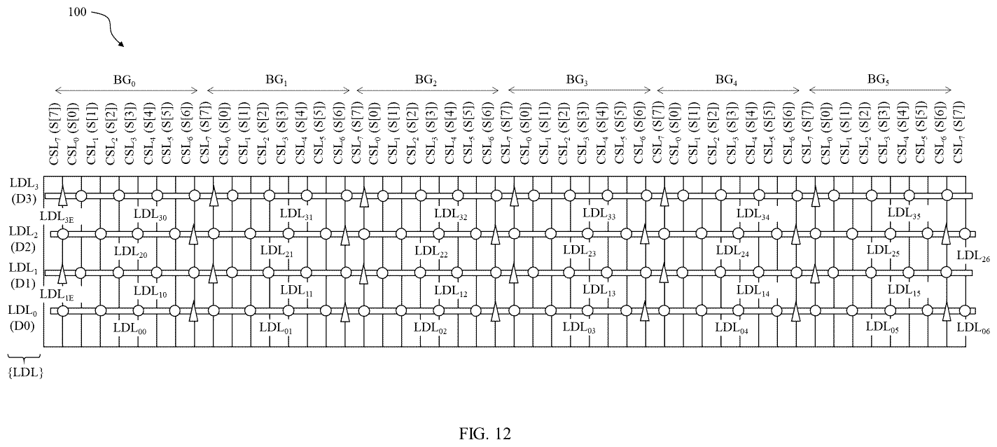

FIG. 12 illustrates an implementation of a portion of the memory device 100 shown in FIG. 1 in accordance with some embodiments. The segmentation of the set of data lines {LDL} shown in FIG. 12 can serve as a more generalized embodiment of segmentation of the set of data lines {LDL} shown in FIG. 10. Each data line can be segmented into more than two line segments. The arrangement of the data lines and bitlines shown in FIG. 12 is substantially identical/similar to that shown in FIG. 6 except that, in each bitline group, bitlines selected in response to activation of the column select lines CSL₇ are arranged at opposite sides of the bitline group. In addition, in some embodiments, the line segment LDL_{1E} included in the data line LDL₁ may be optional; in some embodiments, the line segment LDL_{3E} included in the data line LDL₃ may be optional. As those skilled in the art can appreciate the data line segmentation shown in FIG. 12 and associated data access operation after reading the above paragraphs directed to FIG. 1 to FIG. 11B, further description is omitted here for brevity.

Briefly, by dividing a data line into multiple segments without cutting a shared conductive structure on the data line, the cost of a memory device is relatively low in comparison to the counterpart illustrated in FIG. 3. Moreover, with the use of the proposed data line segmentation scheme, a set of data lines of a memory device can be segmented into line segments to increase memory bandwidth without introducing physical gaps and/or dummy columns in a memory cell array. Each data line can be segmented into two or more line segments to implement a high bandwidth memory device. Data lines that have different numbers of line segments can be of a uniform data width with the use of line segment multiplexing, which can be implemented outside a sense amplifier region to maintain high memory cell density, or by adding a line segment and related circuits at a side of a data line as shown in FIG. 10.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also real ize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a plurality of sets of bitlines, comprising a first set of bitlines and a second set of bitlines;
a set of data lines, each data line comprising a plurality of line segments disposed along an extension direction, the set of data lines comprising a first data line and a second data line, wherein the first data line comprises a first line segment and a second line segment adjacent to each other, and the second data line comprises a first line segment; and
a column selection circuit, electrically coupled between the plurality of sets of bitlines and the set of data lines, the column selection circuit configured to selectively couple a first bitline in the first set of bitlines and a first bitline in the second set of bitlines to the first line segment and the second line segment of the first data line, respectively, and to selectively couple a second bitline in the first set of bitlines and a second bitline in the second set of bitlines to the first line segment of the second data line.

2. The memory device of claim 1, wherein the first data line is segmented into a first number of line segments, the second data line is segmented into a second number of line segments, and the second number is different from the first number.

3. The memory device of claim 1, wherein the first data line is segmented into a first number of line segments, and the second data line is segmented into a second number of line segments; each of the first number and the second number is greater than two.

4. The memory device of claim 1, wherein the column selection circuit is configured to select one set of bitlines from among the plurality of sets of bitlines; when the first set of bitlines is selected, the column selection circuit is configured to couple the first bitline in the first set of bitlines to the first line segment of the first data line to transmit a predetermined data bit; when the second set of bitlines is selected, the column selection circuit is configured to couple the first bitline in the second set of bitlines to the second line segment of the first data line to transmit the predetermined data bit.

5. The memory device of claim 1, wherein the column selection circuit is configured to select one set of bitlines from among the plurality of sets of bitlines; when the first set of bitlines is selected, the column selection circuit is configured to couple the first bitline in the first set of bitlines to the first line segment of the first data line to transmit a predetermined data bit; when the second set of bitlines is selected, the column selection circuit is configured to couple a third bitline in the second set of bitlines to the first line segment of the first data line to transmit the predetermined data bit.

6. The memory device of claim 5, wherein the first bitline in the first set of bitlines is arranged between the third bitline and the first bitline in the second set of bitlines.

7. The memory device of claim 1, wherein the plurality of sets of bitlines further comprises a third set of bitlines, and the column selection circuit is configured to select one set of bitlines from among the set of bitlines; when the third set of bitlines is selected, the column selection circuit is further configured to couple a first bitline in the third set of bitlines to the second line segment of the first data line, and couple a second bitline in the third set of bitlines to a second line segment of the second data line adjacent to the first line segment of the second data line.

8. The memory device of claim 1, wherein the column selection circuit is configured to select one set of bitlines from among the set of bitlines; when the first set of bitlines is selected, the column selection circuit is configured to couple a third bitline in the first set of bitlines to the second line segment of the first data line, and couple a fourth bitline in the first set of bitlines to a second line segment of the second data line adjacent to the first line segment of the second data line.

9. The memory device of claim 1, wherein the column selection circuit is configured to select one set of bitlines from among the set of bitlines; when the second set of bitlines is selected, the column selection circuit is configured to couple a third bitline in the second set of bitlines to a third line segment of the first data line adjacent to the second line segment of the first data line, and couple a fourth bitline in the second set of bitlines to a second line segment of the second data line adjacent to the first line segment of the second data line.

10. The memory device of claim 9, further comprising:
a first multiplexer circuit, having a first output terminal, the first multiplexer circuit being configured to couple one of the first line segment and the second line segment of the first data line to the first output terminal according to whether the second set of bitlines is selected; and
a second multiplexer circuit, having a second output terminal, the second multiplexer circuit being configured to couple one of the second line segment and the third line segment of the first data line to the second output terminal according to whether the second set of bitlines is selected.

11. The memory device of claim 10, further comprising:
a first semiconductor substrate and a second semiconductor substrate stacked one above other, wherein the set of data lines is formed on the first semiconductor substrate, and the first multiplexer circuit and the second multiplexer circuit are formed on the second semiconductor substrate.

12. The memory device of claim 10, wherein the first output terminal of the first multiplexer circuit and the second output terminal of the second multiplexer circuit form a first data width, the second data line forms a second data width, and the first data width is equal to the second data width.

13. A memory device, comprising:
a plurality of sets of bitlines, comprising a first set of bitlines and a second set of bitlines;
a set of data lines, each data line comprising a plurality of line segments separated from each other along an extension direction;
a column selection circuit, selectively couple the plurality of sets of bitlines to the set of data lines; and
a sense amplifier block, electrically coupled to the column selection circuit through the plurality of sets of bitlines;
wherein the column selection circuit comprises a plurality of transistors, each transistor comprises a first node and a second node, the first nodes of the plurality of transistors are electrically coupled to the sense amplifier block, and the second nodes of the plurality of transistors are electrically coupled to the plurality of line segments.

14. The memory device of claim 13, wherein the set of data lines comprises a first data line and a second data line, wherein the first data line comprises a first line segment and a second line segment adjacent to each other, and the second data line comprises a first line segment,
the column selection circuit is configured to selectively couple a first bitline in the first set of bitlines and a first bitline in the second set of bitlines to the first line segment and the second line segment of the first data line, respectively, and to selectively couple a second bitline in the first set of bitlines and a second bitline in the second set of bitlines to the first line segment of the second data line.

15. The memory device of claim 14, wherein the column selection circuit is configured to select one set of bitlines from among the plurality of sets of bitlines; when the first set of bitlines is selected, the column selection circuit is configured to couple the first bitline in the first set of bitlines to the first line segment of the first data line to transmit a predetermined data bit; when the second set of bitlines is selected, the column selection circuit is configured to couple the first bitline in the second set of bitlines to the second line segment of the first data line to transmit the predetermined data bit.

16. The memory device of claim 14, wherein the column selection circuit is configured to select one set of bitlines from among the plurality of sets of bitlines; when the first set of bitlines is selected, the column selection circuit is configured to couple the first bitline in the first set of bitlines to the first line segment of the first data line to transmit a predetermined data bit; when the second set of bitlines is selected, the column selection circuit is configured to couple a third bitline in the second set of bitlines to the first line segment of the first data line to transmit the predetermined data bit.

17. The memory device of claim 14, wherein the plurality of sets of bitlines further comprises a third set of bitlines, and the column selection circuit is configured to select one set of bitlines from among the set of bitlines; when the third set of bitlines is selected, the column selection circuit is further configured to couple a first bitline in the third set of bitlines to the second line segment of the first data line, and couple a second bitline in the third set of bitlines to a second line segment of the second data line adjacent to the first line segment of the second data line.

18. The memory device of claim 14, wherein the column selection circuit is configured to select one set of bitlines from among the set of bitlines; when the first set of bitlines is selected, the column selection circuit is configured to couple a third bitline in the first set of bitlines to the second line segment of the first data line, and couple a fourth bitline in the first set of bitlines to a second line segment of the second data line adjacent to the first line segment of the second data line.

19. The memory device of claim 14, wherein the column selection circuit is configured to select one set of bitlines from among the set of bitlines; when the second set of bitlines is selected, the column selection circuit is configured to couple a third bitline in the second set of bitlines to a third line segment of the first data line adjacent to the second line segment of the first data line, and couple a fourth bitline in the second set of bitlines to a second line segment of the second data line adjacent to the first line segment of the second data line.

20. The memory device of claim 19, further comprising:
a first multiplexer circuit, having a first output terminal, the first multiplexer circuit being configured to couple one of the first line segment and the second line segment of the first data line to the first output terminal according to whether the second set of bitlines is selected; and
a second multiplexer circuit, having a second output terminal, the second multiplexer circuit being configured to couple one of the second line segment and the third line segment of the first data line to the second output terminal according to whether the second set of bitlines is selected.
